(19) United States
(12) Patent Application Publication
(10) Pub. No.: US 2026/0096200 A1
(43) Pub. Date: Apr. 2, 2026

(54) METHOD AND MATERIAL SYSTEM FOR MULTI-THRESHOLD-VOLTAGE GATES IN SEMICONDUCTOR STRUCTURES

(71) Applicant: Applied Materials, Inc., Santa Clara, CA (US)

(72) Inventors: Ashish PAL, San Ramon, CA (US); Gregory COSTRINI, Flanders, NJ (US); Sai Hooi YEONG, Cupertino, CA (US); El Mehdi BAZIZI, San Jose, CA (US); Benjamin COLOMBEAU, San Jose, CA (US); Balasubramanian PRANATHARTHIHARAN, San Jose, CA (US)

(73) Assignee: Applied Materials, Inc., Santa Clara, CA (US)

(21) Appl. No.: 18/899,974

(22) Filed: Sep. 27, 2024

(51) Int. Cl. H01L 27/092; H01L 21/28; H01L 21/8238; H01L 29/06; H01L 29/423; H01L 29/49; H01L 29/66; H01L 29/775; H01L 29/786

(52) U.S. Cl. CPC H10D 84/856; H10D 30/014; H10D 30/43; H10D 30/6735; H10D 30/6739; H10D 30/6757; H10D 62/121; H10D 64/0134; H10D 84/0177; H10D 84/0181; H10D 84/038

(57) ABSTRACT

Methods and structure for gate-all-around (GAA) semiconductor device that can support multiple threshold voltages. The semiconductor device can include a first channel. The first channel can overlaid by a first dielectric layer. The first dielectric layer can be overlaid by a second dielectric layer. The semiconductor device can include a second channel. The second channel can be overlaid by a third dielectric layer. The first dielectric layer can be a doped dielectric layer. The the third dielectric layer can be overlaid by a fourth dielectric layer. The semiconductor device can include a work-function metal layer overlaying the second dielectric layer and the fourth dielectric layer. The work-function metal layer can have a uniform thickness

### TECHNICAL FIELD

The present technology relates to semiconductor systems, processes, and equipment. More specifically, the present technology relates to processes and structures for channels and gates in gate all around and complementary field-effect transistor technologies.

### BACKGROUND

Gate all around (GAA) and complementary field-effect transistor (CFET) technologies are used to create current and future transistors. Both GAA and CFET technologies involve processes being performed on high-aspect ratio structures that are vertically tall but horizontally narrow. Multiple adjacent transistors may need to have different threshold voltages (also referred to as Vt) to enable the formation and creation of multi-Vt devices. However, existing technologies are not able to provide enough different Vt levels with sufficient process margin and manufacturability to create certain multi-Vt devices with a high number of Vt levels.

Thus, there is a need for improved semiconductor structures and corresponding fabrication methods that can be used to increase the number of Vt levels available for multi-Vt devices using high-aspect ratio structures technologies such as GAA and CFET. These and other needs are addressed by the present technology.

### SUMMARY

In some embodiments, a method of forming two or more gates in a gate-all-around (GAA) semiconductor device can include forming a first dielectric layer, wherein a first portion of the first dielectric layer overlays a first channel, and wherein a second portion of the first dielectric layer overlays a second channel; forming a doped dielectric portion of the first dielectric layer by doping the first portion of the first dielectric layer with a dopant; forming a second dielectric layer overlaying the first dielectric layer; and forming a work-function metal layer overlaying the second dielectric layer.

In some embodiments, a method of forming a gate in a gate-all-around (GAA) semiconductor device can include forming a first dielectric layer over a channel; forming a doped dielectric layer by doping the first dielectric layer with a dopant; forming a second dielectric layer overlaying the first dielectric layer; and forming a work-function metal layer overlaying the second dielectric layer.

In some embodiments, a gate-all-around (GAA) semiconductor device may include a first channel, wherein the first channel is overlaid by a first dielectric layer, wherein the first dielectric layer overlaid by a second dielectric layer; a second channel, wherein the second channel is overlaid by a third dielectric layer, wherein the first dielectric layer is a doped dielectric layer, and wherein the third dielectric layer is overlaid by a fourth dielectric layer; and a work-function metal layer overlaying the second dielectric layer and the fourth dielectric layer, wherein the work-function metal layer has a uniform thickness.

In any embodiments, any and all of the following features may be implemented in any combination and without limitation. In some examples, forming a first dielectric layer includes forming a first portion of the first dielectric layer overlays a first channel and a second portion of the first dielectric layer overlays a second channel. In some examples, forming a first dielectric layer includes forming a first dielectric layer over a channel. The first channel can be vertically stacked onto the second channel. The first channel is horizontally positioned in relation to the second channel. Forming the first dielectric layer includes forming the first dielectric layer around all sides of the channel. The first dielectric layer can have a thickness of about 5.0 angstroms. The first channel and the second channel can be comprised of one or more nanotubes or one or more nanosheets. The first channel can be between n-doped regions and the second channel can be between p-doped regions.

In some examples, forming the doped dielectric portion of the first dielectric layer includes doping the first portion of the first dielectric layer overlaying the first channel. In some examples, forming a doped dielectric portion includes doping the entire first dielectric layer with a dopant. In some examples, forming a doped dielectric portion includes forming a dipole material layer over the first dielectric layer. In some examples, forming a doped dielectric portion includes forming a cap metal layer over the dipole material layer. In some examples, forming a doped dielectric portion includes annealing the semiconductor device. In some examples, forming a doped dielectric portion includes removing the dipole material layer and the cap metal layer.

In some examples, forming a work-function metal layer overlaying the second dielectric layer. The work-function metal layer can be a uniform thickness. A first portion of the work-function metal layer can have a first thickness and a second portion of the work-function metal layer have a second thickness. The first portion of the work-function metal layer can overlay a first portion of the second dielectric layer corresponding to the first channel. The second portion of the work-function metal layer can overlay a second portion of the second dielectric layer corresponding to the second channel. The work-function metal layer can be a single metal alloy. The work-function metal layer can have a thickness of about 1.0 nm. The work-function metal layer has a thickness of about 2.0 nm.

The method can further include a first gate being formed with the first channel having a first threshold voltage. The method can include a second gate being formed with the second channel has a second threshold voltage different than the first threshold voltage. The method can further include forming a second doped dielectric portion of the second dielectric layer by doping a second portion of the second dielectric layer. The second portion of the second dielectric layer can overlay the second portion of the first dielectric layer. The method can include forming a third dielectric layer overlaying the second dielectric layer and under the work-function metal layer. A third portion of the first dielectric layer or a third portion of the third dielectric layer can overlay a third channel. The method can further include forming a second doped dielectric layer by doping the second dielectric layer with a second dopant. The method can further include forming a third dielectric layer overlaying the second dielectric layer and under the work-function metal layer.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a top plan view of one embodiment of a processing system of deposition, etching, baking, and curing chambers that may be included or configured according to some embodiments of the present technology.

FIGS. 2A-2B illustrate exemplary schematic cross-sectional structures produced according to some embodiments of the present technology.

FIGS. 3A-3B illustrate exemplary schematic cross-sectional structures produced according to some embodiments of the present technology.

FIGS. 4A-4S illustrate exemplary schematic cross-sectional structures produced according to some embodiments of the present technology.

FIG. 5 illustrates an example flow diagram for forming a multiple threshold voltage semiconductor device according to some embodiments of the present technology.

### DETAILED DESCRIPTION

The present disclosure relates to high-aspect ratio structures in GAA and CFET technologies and the method of fabrication of these structures. In particular, the structure and method of fabrication of the gates in GAA and CFET devices is discussed herein. The gates described herein support the formation of multi-Vt devices that have high numbers of supported Vt levels that also provide sufficient process margin and manufacturability. When forming the gates, the high dielectric constant (also referred to as high-K) dielectric can be formed in layers which can each have a separate dipole drive-in. This can create high-K dielectrics with different band offsets which affect the Fermi level at the interface between the high-K dielectric and the work-function metal. For example, a first gate can have two separate dipole drive-ins on two separate high-K dielectric layers while a second gate may only have a single dipole drive-in on a bottom high-K dielectric layer. In this example, the first gate can have a different Vt than the second gate.

The technology described herein enables the formation of multi-Vt devices that have different threshold voltages for individual gates based on the formation of the high-K dielectric and the individual layers within the high-K dielectric. These gates may all have the same work-function metal material and thickness, yet still have different threshold voltages. Additionally, enabling the formation of multi-Vt devices with the same work-function metal material and thickness further enables sufficient process margin and manufacturability of high-aspect ratio technologies such as GAA and CFET. GAA and CFET can see aspect ratios of about or greater than 10:1 in terms of height compared to width. In some examples, the formation of a high-K dielectric in layers with separate dipole drive-ins can enable more Fermi levels at the interface between the high-K dielectric and the work-function metal than existing technologies. As such, multi-Vt devices formed using the technology described herein may have more supported Vt levels than previous technologies.

Although the remaining disclosure will routinely identify specific processes utilizing the disclosed technology, it will be readily understood that the systems and methods are equally applicable to a variety of other processes as may occur in the described chambers. Accordingly, the technology should not be considered to be so limited as for use with the described processes alone. The disclosure will discuss one possible system that can be used with the present technology before describing systems and methods or operations of exemplary process sequences according to some embodiments of the present technology. It is to be understood that the technology is not limited to the equipment described, and processes discussed may be performed in any number of processing chambers and systems.

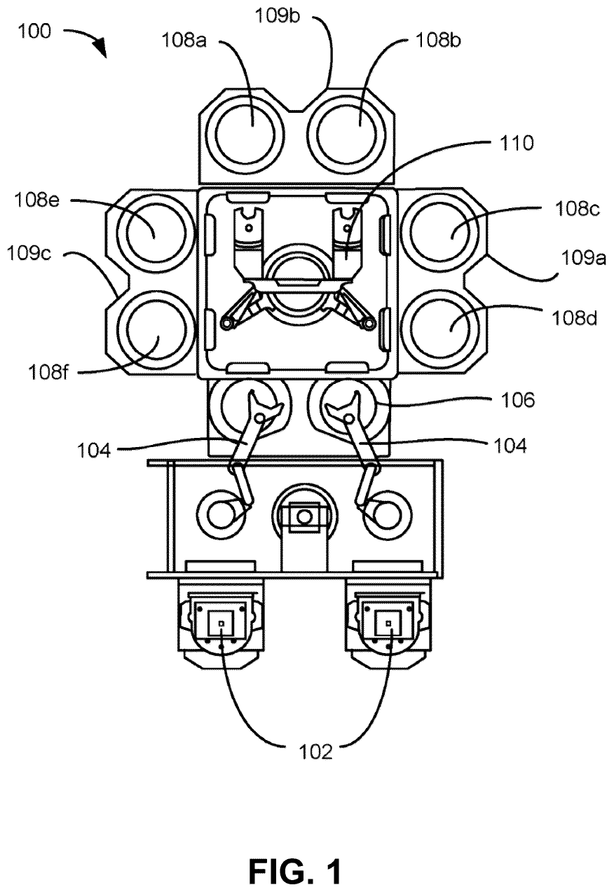

FIG. 1 illustrates a top plan view of one embodiment of a processing system 100 of deposition, etching, baking, and curing chambers that may be included or configured according to some embodiments of the present technology. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f can be outfitted to perform a number of substrate processing operations including the dry etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer. In one configuration, two pairs of the processing chambers, for example 108c-d and 108e-f, may be used to deposit material on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by system 100. Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

System 100, or more specifically chambers incorporated into system 100 or other processing systems, may be used to produce structures according to some embodiments of the present technology.

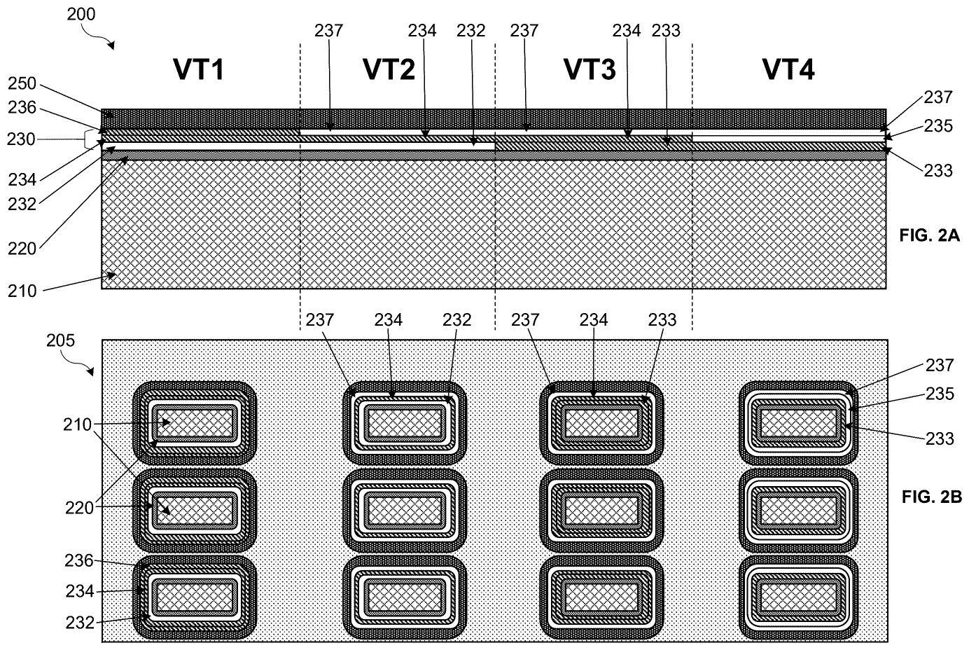

FIG. 2A illustrates an exemplary structure 200 for a gate around a channel in a multi-threshold voltage (Vt) device. The exemplary structure 200 is shown as a planar cross-section of the individual gates for different transistors in the same multi-Vt device for ease of explanation. In some examples, the exemplary structure 200 can be a single semiconductor device with multiple transistors. FIG. 2B illustrates an exemplary structure 205 for a gate around a channel in a multi-Vt device using a gate all around (GAA) architecture. The GAA architecture gate examples of FIG. 2B correspond to the planar structures above them in FIG. 2A. A complimentary field-effect transistor (CFET) architecture can be considered a type of GAA architecture. In some examples, the exemplary structure 205 can be a single semiconductor device with multiple transistors.

The exemplary structure 200 includes a channel 210. The channel 210 can be silicon or any other suitable material for a transistor channel. With reference to FIG. 2B, the channel 210 can be one or more nanotubes or nanosheets. The channel 210 can be overlaid by an interlayer (IL) oxide 220. The IL oxide 220 can be overlaid by a set of high-dielectric constant (high-K) dielectric layers 230. Example high-K dielectrics used for the high-K dielectric layers 230 can include hafnium oxide. The set of high-K dielectric layers 230 can be overlaid by a work function metal (WFM) layer 250 in order to form the gate around the channel. Example WFMs include titanium nitride and titanium aluminum carbide.

In the exemplary structure 200, there are four gate structures which each have different threshold voltages, namely VT1, VT2, VT3, and VT4. The four gate structures have different threshold voltages because the set of high-K dielectric layers 230 are doped differently. In exemplary structure 200, the thickness of the WFM layer 250 can be approximately uniform across all of the gate structures. Having a single WFM layer 250 thickness can be advantageous for increasing manufacturing yields and having sufficient manufacturing tolerances when producing the gate structures. Furthermore, having a single WFM layer 250 thickness can scale to smaller nodes as transistors become smaller and smaller. Additionally, there can be WFM savings by reducing the amount of WFM needed to produce the different threshold voltages in the multi-Vt device. A single WFM thickness can also be useful to increase the amount of high-conductivity metal fill (for example, tungsten) can be used in the multi-Vt device. This lowers the gate resistance and reduces gate voltage differences between each channel in a device, which in turn decreases device variability.

In relation to VT1, the set of high-K dielectric layers 230 includes a first undoped high-K dielectric layer 232 overlaid by a second doped high-K dielectric layer 234 overlaid by a third doped high-K dielectric layer 236. In relation to VT2, the set of high-K dielectric layers 230 includes a first undoped high-K dielectric layer 232 overlaid by a second doped high-K dielectric layer 234 overlaid by a third undoped high-K dielectric layer 237. In relation to VT3, the set of high-K dielectric layers 230 includes a first doped high-K dielectric layer 233 overlaid by a second doped high-K dielectric layer 234 overlaid by a third undoped high-K dielectric layer 237. In relation to VT4, the set of high-K dielectric layers 233 includes a first doped high-K dielectric layer 232 overlaid by a second undoped high-K dielectric layer 235 overlaid by a third undoped high-K dielectric layer 237. By doping the individual layers of the set of high-K dielectric layers differently, the overall set of high-K dielectric layers can have different band offsets. By having different band offsets, the Fermi level at the interface between the high-K dielectric and the work-function metal can be different to create different threshold voltages.

In some examples, the thickness of the set of high-K dielectric layers 230 can be 30.0 angstroms or less. In some examples, the thickness of the set of high-K dielectric layers 230 can be about or less than 30.0 angstroms, about or less than 25.0 angstroms, about or less than 20.0 angstroms, about or less than 15.0 angstroms, about or less than 10.0 angstroms, or about or less than 5.0 angstroms. The thickness of each individual high-K dielectric layer (for example, high-K dielectric layers 232, 234, 236) can be near equal thickness or equal thickness. In some examples, the number of high-K dielectric layers in the set of high-K dielectric layers can be two, three, four, or five, or greater.

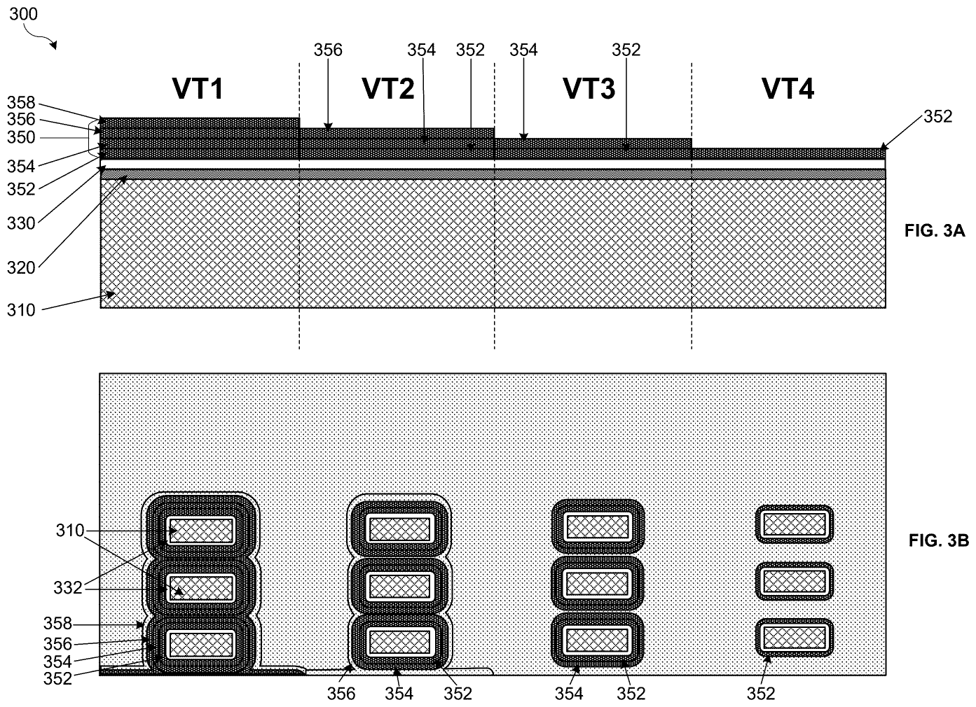

FIG. 3A illustrates an exemplary structure 300 for a gate around a channel in a multi-threshold voltage (Vt) device. The exemplary structure 300 is shown as a planar cross-section of the individual gates for different transistors in the same multi-Vt device for ease of explanation. In some examples, the exemplary structure 300 can be a single semiconductor device with multiple transistors. FIG. 3B illustrates an exemplary structure 305 for a gate around a channel in a multi-Vt device using a gate all around (GAA) architecture. A complimentary field-effect transistor (GAA) architecture can be considered a type of GAA architecture. In some examples, the exemplary structure 305 can be a single semiconductor device with multiple transistors.

The exemplary structure 300 includes a channel 310. The channel 310 can silicon or any other suitable material for a transistor channel. With reference to FIG. 3B, the channel 310 can be one or more nanotubes or nanosheets. The channel 310 can be overlaid by an IL oxide 320. The IL oxide 320 can be overlaid by a high-K dielectric layer 330. The high-K dielectric layer 330 can be overlaid by a one or more work function metal (WFM) layers 350 in order to form the gate around the channel. The WFM layers 352, 354, 356, 358 can be uniform thickness. In some examples, the WFM layers 352, 354, 356, 358 are a homogenous metal and are not distinguishable as individual layers. In this way, the WFM layer 350 for each of VT1, VT2, VT3, and VT4 can be referred to as having different WFM thicknesses.

In the exemplary structure 300, there are four gate structures which each have different threshold voltages, namely VT1, VT2, VT3, and VT4. The four gate structures have different threshold voltages because the thickness of the work function metal is different. In relation to VT1, the WFM layers 350 includes a WFM layers 352, 354, 356, 358. In relation to VT2, the WFM layers 350 includes a WFM layers 352, 354, 356. In relation to VT3, the WFM layers 350 includes a WFM layers 352, 354. In relation to VT4, the WFM layers 350 includes a WFM layers 352. The different amount of WFM metal in the WFM layers 350 cause the different gates to have different threshold voltages VT1, VT2, VT3, and VT4. In some examples, the WFM layers 350 may pinch-off when the distance between nanosheets of the channel when the thickness of the WFM layers 350 exceeds a threshold. This can potentially decrease manufacturing viability as well as decrease the number of different threshold voltages in a multi-Vt device that can be supported by the use of different WFM thicknesses.

In some examples, the total thickness of the WFM layers 350 can be about or less than 8.0 nm, about or less than 7.9 nm, about or less than 7.8 nm, about or less than 7.7 nm, about or less than 7.6 nm, about or less than 7.5 nm, about or less than 7.4 nm, about or less than 7.3 nm, about or less than 7.2 nm, about or less than 7.1 nm, about or less than 7.0 nm, about or less than 6.9 nm, about or less than 6.8 nm, about or less than 6.7 nm, about or less than 6.6 nm, about or less than 6.5 nm, about or less than 6.4 nm, about or less than 6.3 nm, about or less than 6.2 nm, about or less than 6.1 nm, about or less than 6.0 nm, about or less than 5.9 nm, about or less than 5.8 nm, about or less than 5.7 nm, about or less than 5.6 nm, about or less than 5.5 nm, about or less than 5.4 nm, about or less than 5.3 nm, about or less than 5.2 nm, about or less than 5.1 nm, about or less than 5.0 nm, about or less than 4.9 nm, about or less than 4.8 nm, about or less than 4.7 nm, about or less than 4.6 nm, about or less than 4.5 nm, about or less than 4.4 nm, about or less than 4.3 nm, about or less than 4.2 nm, about or less than 4.1 nm, about or less than 4.0 nm, about or less than 3.9 nm, about or less than 3.8 nm, about or less than 3.7 nm, about or less than 3.6 nm, about or less than 3.5 nm, about or less than 3.4 nm, about or less than 3.3 nm, about or less than 3.2 nm, about or less than 3.1 nm, about or less than 3.0 nm, about or less than 2.9 nm, about or less than 2.8 nm, about or less than 2.7 nm, about or less than 2.6 nm, about or less than 2.5 nm, about or less than 2.4 nm, about or less than 2.3 nm, about or less than 2.2 nm or less, about or less than 2.1 nm, about or less than 2.0 nm, about or less than 1.9 nm, about or less than 1.8 nm, about or less than 1.7 nm, about or less than 1.6 nm, about or less than 1.5 nm, about or less than 1.4 nm, about or less than 1.3 nm, about or less than 1.2 nm, about or less than 1.1 nm, about or less than 1.0 nm, about or less than 0.9 nm, about or less than 0.8 nm, about or less than 0.7 nm, about or less than 0.6 nm, about or less than 0.5 nm, or less. In some examples, the number of WFM layers in the set of WFM layers 350 can be one, two, three, four, or five, or greater. The thickness of each WFM layer (for example, WFM layers 352, 354, 356, 358) can be near equal thickness or equal thickness. In some examples, the number of WFM layers in the set of WFM layers can be two, three, four, or five, or greater.

In some implementations, the exemplary structure 200 and exemplary structure 300 can be combined such that both multiple layers of doped and undoped high-K dielectric can be used in conjunction with multiple WFM thicknesses. For example, there may be three different high-K dielectric layers as shown in exemplary structure 200 and four different WFM thicknesses as shown in exemplary structure 300. In some implementations, both the number of threshold voltages offered through the use of different high-K dielectric layers and number of different WFM thicknesses may be multiplied together to determine a total number of different threshold voltages offered by the multi-Vt device. In some implementations, the different threshold voltages may be fewer than that multiplied value due to manufacturing and other constraints.

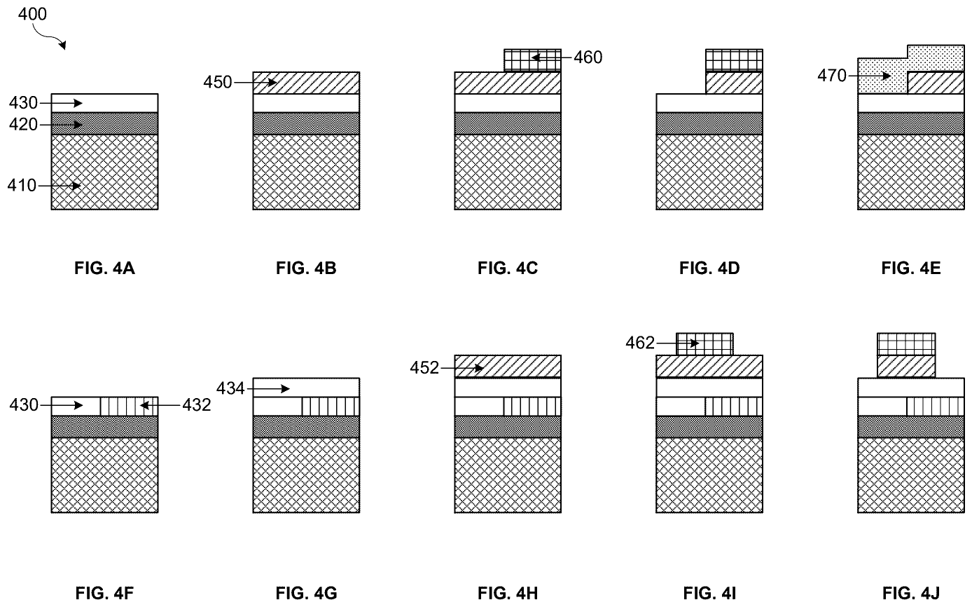

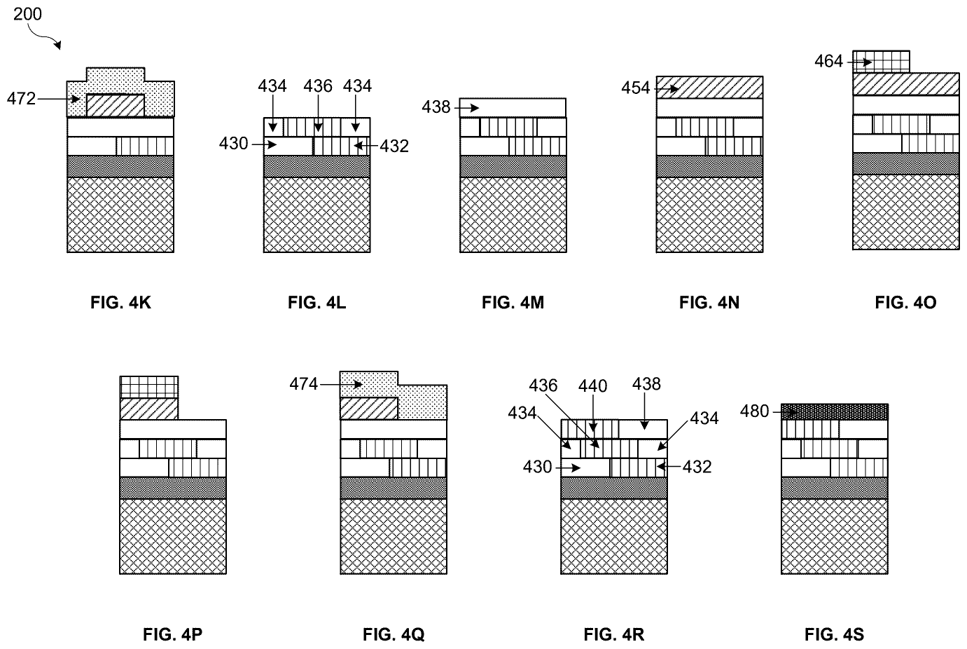

FIGS. 4A-4S illustrate a process 400 in a series of schematics. It is to be understood that FIGS. 4A-4S illustrate only partial schematic views. Process 400 may or may not involve optional operations to develop the semiconductor structures to a particular fabrication operation. It is to be understood that process 400 may be performed on any number of semiconductor structures. FIGS. 4A-4S are presented in a simplified planar format. However, the concepts apply to the GAA and CFET transistor architectures as described in relation to FIGS. 2A, 2B, 3A, and 3B.

As illustrated in FIG. 4A, a semiconductor structure for a channel and gate may include a channel 410 (for example, the channel 210 of FIGS. 2A-2B and the channel 310 of FIGS. 3A-3B). The channel 410 can be any silicon or any other suitable material for a transistor channel. The channel 410 can be overlaid by an IL oxide 420. The IL oxide 420 can be overlaid by a first undoped dielectric layer 430.

As illustrated in FIG. 4B, a dipole metal layer 450 can be overlaid onto the first undoped dielectric layer 430. The dipole metal layer 450 can be any type of dopant material. For example, a dipole metal layer 450 can be aluminum for a p-channel metal-oxide-semiconductor (pMOS) field-effect transistor or lanthanum for a n-channel metal-oxide-semiconductor (nMOS) field-effect transistor. As illustrated in FIG. 4C, a photoresist 460 can be applied and etched via a photolithographic process. In this way, the photoresist 460 only overlays a portion of the dipole metal layer 450.

As illustrated in FIG. 4D, the dipole metal layer 450 is then etched such that only the dipole metal material of the dipole metal layer 450 under the photoresist 460 remains. As illustrated in FIG. 4E, the photoresist 460 is stripped away from the dipole metal layer 450 and a cap metal layer 470 is deposited over both the exposed first undoped dielectric layer 430 and the dipole metal layer 450. In some implementations, the cap metal can be titanium nitride.

As illustrated in FIG. 4F, a dipole drive-in process is performed to cause dopants (for example, the source dipole metal) from the dipole metal layer 450 to be deposited into the first undoped dielectric layer 430 to form a first doped dielectric layer 432. After the dipole drive-in process is completed, the cap metal layer 470 and the dipole metal layer 450 are stripped to expose both the first undoped dielectric layer 430 and the first doped dielectric layer 432.

In some implementations, the dipole drive-in process can include annealing the semiconductor structure. During the annealing process, the processing chamber for the semiconductor structure can be maintained at a temperature of about 900° C. In some examples, the temperature maintained in the processing chamber for the annealing process can be more than or about 700° C., more than or about 750° C., more than or about 800° C., more than or about 850° C., more than or about 900° C., more than or about 950° C., more than or about 1000° C., more than or about 1050° C., more than or about 1100° C., more than or about 1150° C., or more, although the temperature may also be included in ranges between any two of these stated numbers or within any smaller range encompassed by any of the stated ranges.

As illustrated in FIG. 4G, a second undoped dielectric layer 434 is formed over the first undoped dielectric layer 430 and the first doped dielectric layer 432. The second undoped dielectric layer 434 can have the same characteristics as the first undoped dielectric layer 430 of FIG. 4A. As illustrated in FIG. 4H, a second dipole metal layer 452 can be overlaid onto the second undoped dielectric layer 432. The second dipole metal layer 452 can have the same characteristics as the dipole metal layer 450 of FIG. 4B.

As illustrated in FIG. 4I, a photoresist 462 can be applied and etched via a photolithographic process. In this way, the photoresist 462 only overlays a portion of the second dipole metal layer 452. Here, the photoresist 462 overlays a portion of the dipole metal layer 452 that corresponds to both portions of the first undoped dielectric layer 430 and the first doped dielectric layer 432. Here, we are trying to dope different regions of the second undoped dielectric layer 434 as compared to the corresponding regions forming the first doped dielectric layer 432.

As illustrated in FIG. 4J, the second dipole metal layer 452 is then etched such that only the dipole metal material of the second dipole metal layer 452 under the photoresist 462 remains. As illustrated in FIG. 4K, the photoresist 462 is stripped away from the second dipole metal layer 452 and a second cap metal layer 472 is deposited over both the exposed second undoped dielectric layer 434 and the second dipole metal layer 452. The second cap metal layer 472 can have the same characteristics as the cap metal layer 470 of FIG. 4E.

As illustrated in FIG. 4L, a second dipole drive-in process is performed to cause dopants (for example, the source dipole metal) from the second dipole metal layer 452 to be deposited into the second undoped dielectric layer 434 to form a second doped dielectric layer 436. After the dipole drive-in process is completed, the second cap metal layer 472 and the second dipole metal layer 452 are stripped to expose both the second undoped dielectric layer 434 and the second doped dielectric layer 436. Here, it can be seen that the second doped dielectric layer 436 overlays a portion of the first undoped dielectric layer 430 and a portion of the first doped dielectric layer 432. In some implementations, the second dipole drive-in process can include annealing the semiconductor structure. this annealing process can have similar characteristics to the annealing process described in relation to FIG. 4F.

As illustrated in FIG. 4M, a third undoped dielectric layer 438 is formed over the second undoped dielectric layer 434 and the second doped dielectric layer 436. The third undoped dielectric layer 438 can have the same characteristics as the first undoped dielectric layer 430 of FIG. 4A. As illustrated in FIG. 4N, a third dipole metal layer 454 can be overlaid onto the third undoped dielectric layer 438. The third dipole metal layer 454 can have the same characteristics as the dipole metal layer 450 of FIG. 4B.

As illustrated in FIG. 4O, a photoresist 464 can be applied and etched via a photolithographic process. In this way, the photoresist 464 only overlays a portion of the third dipole metal layer 454. Here, the photoresist 464 overlays a portion of the third dipole metal layer 454 that corresponds to both portions of the second undoped dielectric layer 434 and the second doped dielectric layer 436. Here, we are trying to dope different regions of the third undoped dielectric layer 438 as compared to the corresponding regions forming the first doped dielectric layer 432 and the second doped dielectric layer 436.

As illustrated in FIG. 4P, the third dipole metal layer 454 is then etched such that only the dipole metal material of the third dipole metal layer 454 under the photoresist 464 remains. As illustrated in FIG. 4Q, the photoresist 464 is stripped away from the third dipole metal layer 454 and a third cap metal layer 474 is deposited over both the exposed third undoped dielectric layer 438 and the third dipole metal layer 454. The third cap metal layer 474 can have the same characteristics as the cap metal layer 470 of FIG. 4E.

As illustrated in FIG. 4R, a third dipole drive-in process is performed to cause dopants (for example, the source dipole metal) from the third dipole metal layer 454 to be deposited into the third undoped dielectric layer 438 to form a third doped dielectric layer 440. After the dipole drive-in process is completed, the third cap metal layer 474 and the third dipole metal layer 454 are stripped to expose both the third undoped dielectric layer 438 and the third doped dielectric layer 440. Here, it can be seen that the third doped dielectric layer 440 overlays a portion of the second undoped dielectric layer 434 and a portion of the second doped dielectric layer 436. In some implementations, the third dipole drive-in process can include annealing the semiconductor structure. this annealing process can have similar characteristics to the annealing process described in relation to FIG. 4F.

The process 400 described herein include three undoped dielectric layers and three corresponding drive-in processes (for example, in relation to FIGS. 4A-4F). However, any number undoped dielectric layers and corresponding drive-in processes can be used. There can be two undoped dielectric layers and two corresponding drive-in processes or four, five, or more undoped dielectric layers and corresponding drive-in processes.

As illustrated in FIG. 4S, a work-function metal layer 480 can be overlaid onto the third undoped dielectric layer 438 and the third doped dielectric layer 440. Each section of the work-function metal layer 480 can correspond to gates that have different threshold voltages as described herein.

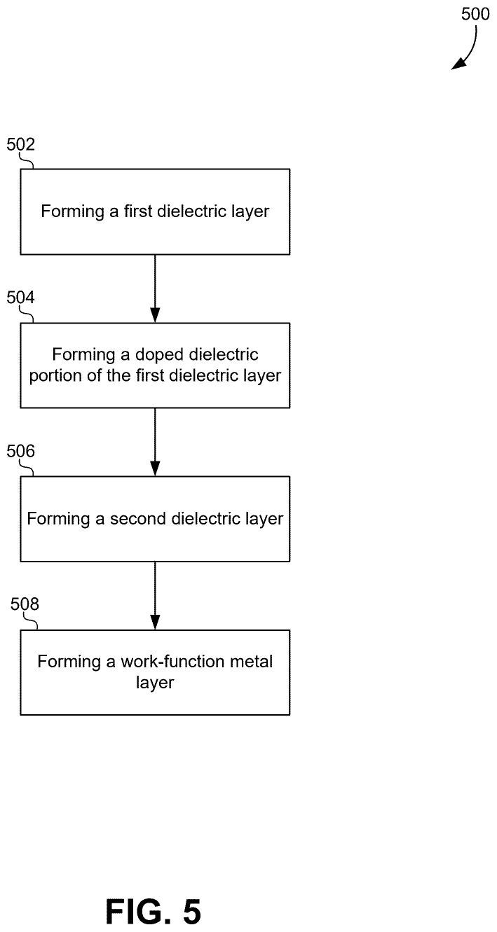

FIG. 5 illustrates a flowchart of exemplary operations in a method 500 of forming one or more gates in a gate all around semiconductor device according to some embodiments of the present technology. Method 500 may include one or more operations prior to the initiation of the method 500. Method 500 may include a number of optional operations, which may or may not be specifically associated with some embodiments of methods according to embodiments of the present technology.

It should be appreciated that the specific steps illustrated in FIG. 5 provide particular methods of forming a gate all around semiconductor device according to various embodiments. Other sequences of steps may also be performed according to alternative embodiments. For example, alternative embodiments may perform the steps outlined above in a different order. Moreover, the individual steps illustrated in FIG. 5 may include multiple sub-steps that may be performed in various sequences as appropriate to the individual step. Furthermore, additional steps may be added or removed depending on the particular applications. Many variations, modifications, and alternatives also fall within the scope of this disclosure.

At operation 502, the method 500 may include forming a first dielectric layer. In some examples, forming a first dielectric layer includes forming a first portion of the first dielectric layer overlays a first channel and a second portion of the first dielectric layer overlays a second channel. In some examples, forming a first dielectric layer includes forming a first dielectric layer over a channel. The first channel can be vertically stacked onto the second channel. The first channel is horizontally positioned in relation to the second channel. Forming the first dielectric layer includes forming the first dielectric layer around all sides of the channel. The first dielectric layer can have a thickness of about 5.0 angstroms. The first channel and the second channel can be comprised of one or more nanotubes or one or more nanosheets. The first channel can be between n-doped regions and the second channel can be between p-doped regions.

At operation 504, the method 500 may include forming a doped dielectric portion of the first dielectric layer by doping the first dielectric layer with a dopant. In some examples, forming the doped dielectric portion of the first dielectric layer includes doping the first portion of the first dielectric layer overlaying the first channel. In some examples, forming a doped dielectric portion includes doping the entire first dielectric layer with a dopant. In some examples, forming a doped dielectric portion includes forming a dipole material layer over the first dielectric layer. In some examples, forming a doped dielectric portion includes forming a cap metal layer over the dipole material layer. In some examples, forming a doped dielectric portion includes annealing the semiconductor device. In some examples, forming a doped dielectric portion includes removing the dipole material layer and the cap metal layer.

At operation 506, the method 500 may include forming a second dielectric layer overlaying the first dielectric layer. The second dielectric layer can have a thickness of about 5.0 angstroms.

At operation 508, the method 500 may include forming a work-function metal layer overlaying the second dielectric layer. The work-function metal layer can be a uniform thickness. A first portion of the work-function metal layer can have a first thickness and a second portion of the work-function metal layer have a second thickness. The first portion of the work-function metal layer can overlay a first portion of the second dielectric layer corresponding to the first channel. The second portion of the work-function metal layer can overlay a second portion of the second dielectric layer corresponding to the second channel. The work-function metal layer can be a single metal alloy. The work-function metal layer can have a thickness of about 1.0 nm. The work-function metal layer can have a thickness of about 2.0 nm.

The method 500 can further include a first gate being formed with the first channel having a first threshold voltage. The method 500 can include a second gate being formed with the second channel has a second threshold voltage different than the first threshold voltage. The method 500 can further include forming a second doped dielectric portion of the second dielectric layer by doping a second portion of the second dielectric layer. The second portion of the second dielectric layer can overlay the second portion of the first dielectric layer. The method 500 can include forming a third dielectric layer overlaying the second dielectric layer and under the work-function metal layer. A third portion of the first dielectric layer or a third portion of the third dielectric layer can overlay a third channel.

The method 500 can further include forming a second doped dielectric layer by doping the second dielectric layer with a second dopant. The method 500 can further include forming a third dielectric layer overlaying the second dielectric layer and under the work-function metal layer.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of forming two or more gates in a gate-all-around (GAA) semiconductor device comprising:
forming a first dielectric layer, wherein a first portion of the first dielectric layer overlays a first channel, and wherein a second portion of the first dielectric layer overlays a second channel;
forming a doped dielectric portion of the first dielectric layer by doping the first portion of the first dielectric layer with a dopant;
forming a second dielectric layer overlaying the first dielectric layer; and
forming a work-function metal layer overlaying the second dielectric layer.

2. The method of claim 1 wherein the work-function metal layer is uniform thickness.

3. The method of claim 1, wherein a first gate formed with the first channel has a first threshold voltage and a second gate formed with the second channel has a second threshold voltage different than the first threshold voltage.

4. The method of claim 1, wherein the first channel is vertically stacked onto the second channel.

5. The method of claim 1, further comprising:
forming a second doped dielectric portion of the second dielectric layer by doping a second portion of the second dielectric layer, wherein the second portion of the second dielectric layer overlays the second portion of the first dielectric layer; and
forming a third dielectric layer overlaying the second dielectric layer and under the work-function metal layer.

6. The method of claim 5, wherein a third portion of the first dielectric layer overlays a third channel.

7. The method of claim 1, wherein a first portion of the work-function metal layer has a first thickness and a second portion of the work-function metal layer has a second thickness, wherein the first portion of the work-function metal layer overlays a first portion of the second dielectric layer corresponding to the first channel, and wherein the second portion of the work-function metal layer overlays a second portion of the second dielectric layer corresponding to the second channel.

8. A method of forming a gate in a gate-all-around (GAA) semiconductor device comprising:
forming a first dielectric layer over a channel;
forming a doped dielectric layer by doping the first dielectric layer with a dopant;
forming a second dielectric layer overlaying the first dielectric layer; and
forming a work-function metal layer overlaying the second dielectric layer.

9. The method of claim 8, wherein forming the doped dielectric layer includes:
forming a dipole material layer over the first dielectric layer;
forming a cap metal layer over the dipole material layer;
annealing the semiconductor device; and
removing the dipole material layer and the cap metal layer.

10. The method of claim 8, further comprising:
forming a second doped dielectric layer by doping the second dielectric layer with a second dopant; and
forming a third dielectric layer overlaying the second dielectric layer and under the work-function metal layer.

11. The method of claim 8, wherein forming the first dielectric layer includes forming the first dielectric layer around all sides of the channel.

12. The method of claim 8, wherein the work-function metal layer is a single metal alloy.

13. The method of claim 8, wherein the work-function metal layer has a thickness of about 1.0 nm.

14. The method of claim 8, wherein the first dielectric layer has a thickness of about 5.0 angstroms.

15. A gate-all-around (GAA) semiconductor device comprising:
a first channel, wherein the first channel is overlaid by a first dielectric layer, wherein the first dielectric layer overlaid by a second dielectric layer;
a second channel, wherein the second channel is overlaid by a third dielectric layer, wherein the first dielectric layer is a doped dielectric layer, and wherein the third dielectric layer is overlaid by a fourth dielectric layer; and
a work-function metal layer overlaying the second dielectric layer and the fourth dielectric layer, wherein the work-function metal layer has a uniform thickness.

16. The semiconductor device of claim 15, wherein the first channel and the second channel are comprised of one or more nanotubes.

17. The semiconductor device of claim 15, wherein a first gate formed with the first channel has a first threshold voltage and a second gate formed with the second channel has a second threshold voltage different than the first threshold voltage.

18. The semiconductor device of claim 15, wherein the work-function metal layer is a single metal alloy.

19. The semiconductor device of claim 15, wherein the work-function metal layer has a thickness of about 2.0 nm.

20. The semiconductor device of claim 15, wherein the first channel is between n-doped regions and wherein the second channel is between p-doped regions.
